(19) United States
(12) Patent Application Publication
(10) Pub. No.: US 2026/0223537 A1
(43) Pub. Date: Jul. 30, 2026

(54) DISPLAY DEVICE

(71) Applicant: Sharp Display Technology Corporation, Kameyama City, Mie (JP)

(72) Inventor: Shogo MURASHIGE, Kameyama City, Mie (JP)

(21) Appl. No.: 19/149,068

(22) PCT Filed: Jan. 18, 2023
(86) PCT No.: PCT/JP2023/001340

§ 371 Date: Jul. 17, 2025

(51) Int. Cl. H10K 59/121; G09G 3/3233; H10D 86/01; H10D 86/40; H10D 86/60; H10K 59/12

(52) U.S. Cl. CPC H10K 59/1213; G09G 3/3233; H10D 86/0221; H10D 86/423; H10D 86/60; H10K 59/1201; G09G 2300/043; G09G 2300/0819; G09G 2310/08

(57) ABSTRACT

Each subpixel is provided with a first TFT including a first semiconductor layer made of polysilicon, a second TFT including a second semiconductor layer made of an oxide semiconductor, and a third TFT including a third semiconductor layer made of an oxide semiconductor. The second TFT has a top contact structure in which the second TFT is electrically connected to a third terminal electrode and a fourth terminal electrode on an upper side of the second semiconductor layer. The third TFT has a bottom contact structure in which the third TFT is electrically connected to a fifth terminal electrode and a sixth terminal electrode on a lower side of the third semiconductor layer.

### TECHNICAL FIELD

The disclosure relates to a display device.

### BACKGROUND ART

In recent years, as a display device replacing a liquid crystal display device, a self-luminous organic electroluminescence (hereinafter, also referred to as “EL”) display device using an organic EL element has attracted attention. In the organic EL display device, a plurality of thin film transistors (hereinafter, also referred to as “TFTs”) are provided for each subpixel, which is the smallest unit of an image. Here, well-known examples of a semiconductor layer constituting the TFT are a semiconductor layer made of polysilicon having high mobility, a semiconductor layer made of an oxide semiconductor such as In—Ga—Zn—O having a low leakage current, and the like.

For example, PTL 1 discloses a semiconductor device including a first TFT including a first active layer mainly containing a first oxide semiconductor and a second TFT including a second active layer mainly containing a second oxide semiconductor having a higher mobility than that of the first oxide semiconductor. The first active layer and the second active layer are disposed on the same insulating layer and in contact with the same insulating layer.

### CITATION LIST

### Patent Literature

PTL 1: WO 2016/006530

### SUMMARY

### Technical Problem

Now, in an organic EL display device having a hybrid structure in which a TFT using polysilicon and a TFT using an oxide semiconductor are provided in each subpixel, for example, it has been proposed that polysilicon is used for a TFT requiring a drive force and an oxide semiconductor is used for a TFT requiring charge retention. Further, characteristics required for the TFT using the oxide semiconductor vary depending on functions as the transistor, and it is difficult to provide characteristics suitable for each function with one structure. Therefore, there is room for improvement.

The disclosure has been conceived in view of the above point, and an object thereof is to appropriately adjust characteristics of a TFT using an oxide semiconductor in a display device having a hybrid structure.

### Solution to Problem

In order to accomplish the above object, according to the disclosure, there is provided a display device including a base substrate and a thin film transistor layer provided on the base substrate, wherein the thin film transistor layer is provided with, for each of subpixels constituting a display region, a first thin film transistor including a first semiconductor layer made of polysilicon, a second thin film transistor including a second semiconductor layer made of an oxide semiconductor, and a third thin film transistor including a third semiconductor layer made of an oxide semiconductor, the first thin film transistor includes the first semiconductor layer in which a first conductor region and a second conductor region are defined to be separated from each other and a first channel region is defined between the first conductor region and the second conductor region, a first gate electrode provided on the first semiconductor layer, the first gate electrode being superimposed over the first channel region with a first inorganic insulating film interposed between the first gate electrode and the first channel region, and a first terminal electrode and a second terminal electrode separated from each other on a side opposite to the base substrate relative to the first gate electrode, the first terminal electrode and the second terminal electrode being respectively electrically connected to the first conductor region and the second conductor region, the second thin film transistor includes the second semiconductor layer in which a third conductor region and a fourth conductor region are defined to be separated from each other and a second channel region is defined between the third conductor region and the fourth conductor region, a second gate electrode provided on the second semiconductor layer, the second gate electrode being superimposed over the second channel region with a second inorganic insulating film interposed between the second gate electrode and the second channel region, and a third terminal electrode and a fourth terminal electrode separated from each other on a side opposite to the base substrate relative to the second gate electrode, the third terminal electrode and the fourth terminal electrode being respectively electrically connected to the third conductor region and the fourth conductor region, and the third thin film transistor includes the third semiconductor layer in which a fifth conductor region and a sixth conductor region are defined to be separated from each other and a third channel region is defined between the fifth conductor region and the sixth conductor region, a first relay electrode and a second relay electrode provided on a side of the base substrate of the third semiconductor layer, the first relay electrode and the second relay electrode being disposed respectively in contact with the fifth conductor region and the sixth conductor region, a third gate electrode provided on the third semiconductor layer, the third gate electrode being superimposed over the third channel region with a third inorganic insulating film interposed between the third gate electrode and the third channel region, and a fifth terminal electrode and a sixth terminal electrode separated from each other on a side opposite to the base substrate relative to the third gate electrode, the fifth terminal electrode and the sixth terminal electrode being respectively electrically connected to the first relay region and the second relay region.

### Advantageous Effects of Disclosure

According to the disclosure, in the display device having the hybrid structure, characteristics of a TFT using an oxide semiconductor can be appropriately adjusted.

### BRIEF DESCRIPTION OF DRAWINGS

FIG. 1 is a block diagram of an overall configuration of an organic EL display device according to a first embodiment of the disclosure.

FIG. 2 is an equivalent circuit diagram of a pixel circuit of a TFT layer constituting the organic EL display device according to the first embodiment of the disclosure.

FIG. 3 is a plan view illustrating a schematic configuration of the TFT layer constituting the organic EL display device according to the first embodiment of the disclosure.

FIG. 4 is a cross-sectional view of the organic EL display device according to the first embodiment of the disclosure.

FIG. 5 is a cross-sectional view of the organic EL layer constituting the organic EL display device according to the first embodiment of the disclosure.

FIG. 6 is a timing chart for describing an operation of a pixel circuit of the organic EL display device according to the first embodiment of the disclosure.

FIG. 7 is a cross-sectional view illustrating a part of forming the TFT layer constituting the organic EL display device according to the first embodiment of the disclosure.

FIG. 8 is a cross-sectional view illustrating a part of forming the TFT layer subsequent to the process illustrated in FIG. 7.

FIG. 9 is a cross-sectional view of an organic EL display device according to a second embodiment of the disclosure.

FIG. 10 is a cross-sectional view illustrating a part of forming a TFT layer constituting the organic EL display device according to the second embodiment of the disclosure.

FIG. 11 is a cross-sectional view illustrating a part of forming the TFT layer subsequent to the process illustrated in FIG. 10.

FIG. 12 is a cross-sectional view illustrating a part of forming the TFT layer subsequent to the process illustrated in FIG. 11.

FIG. 13 is a cross-sectional view of an organic EL display device according to a third embodiment of the disclosure.

FIG. 14 is a cross-sectional view illustrating a part of forming a TFT layer constituting the organic EL display device according to the third embodiment of the disclosure.

FIG. 15 is a cross-sectional view illustrating a part of forming the TFT layer subsequent to the process illustrated in FIG. 14.

FIG. 16 is a cross-sectional view illustrating a part of forming the TFT layer subsequent to the process illustrated in FIG. 15.

FIG. 17 is a cross-sectional view illustrating a part of forming the TFT layer subsequent to the process illustrated in FIG. 16.

### DESCRIPTION OF EMBODIMENTS

Embodiments of a technique according to the disclosure will be described below in detail with reference to the drawings. Note that the technique according to the disclosure is not limited to each of the embodiments to be described below.

### First Embodiment

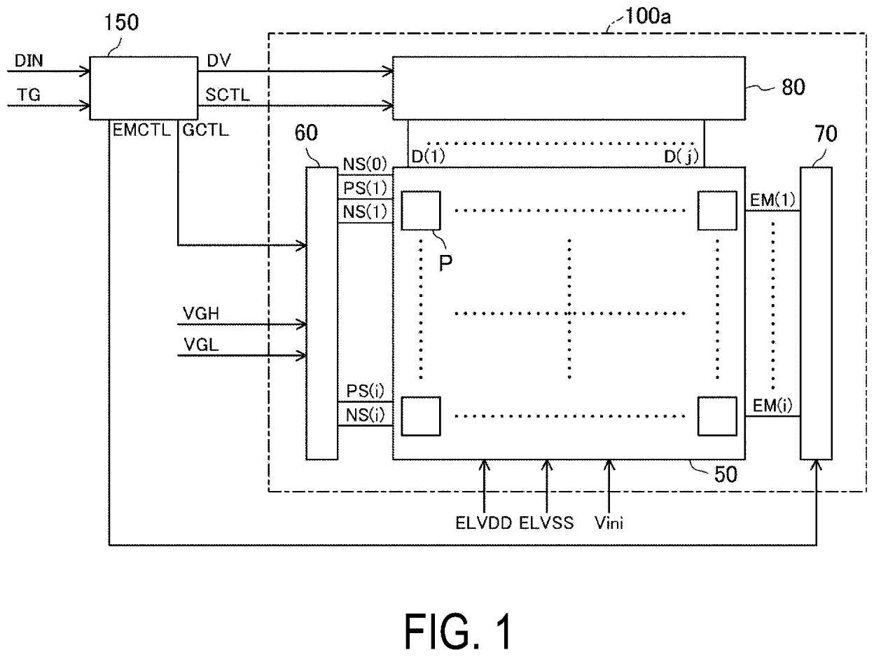

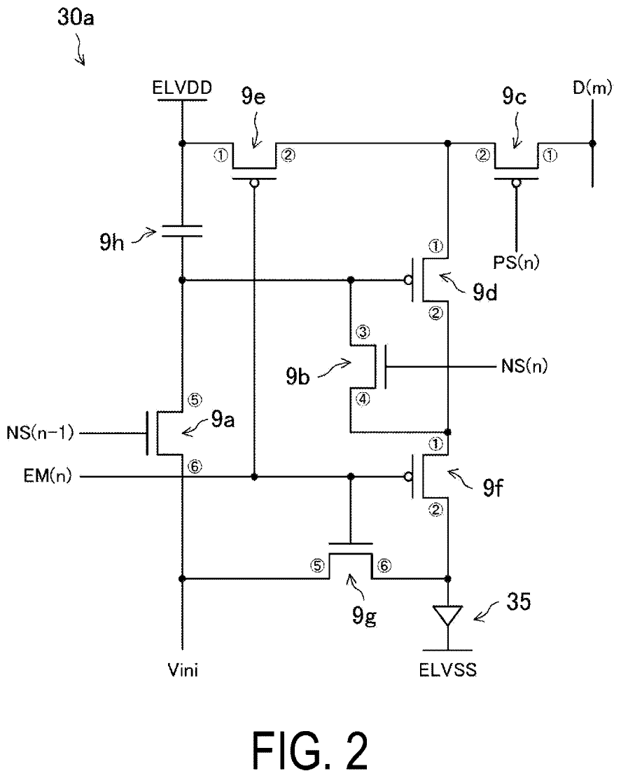

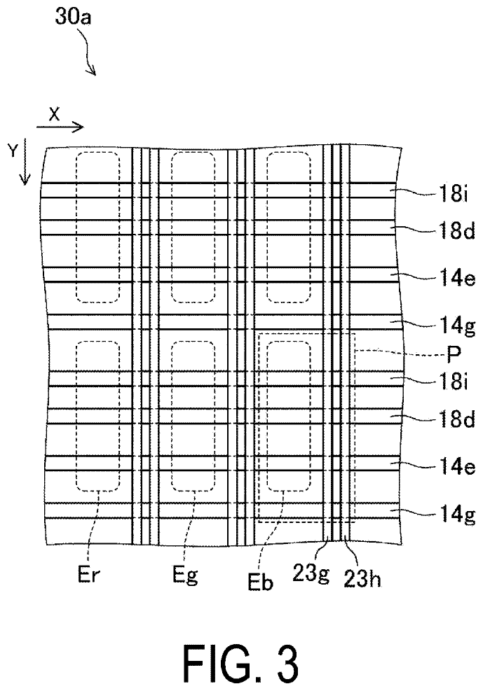

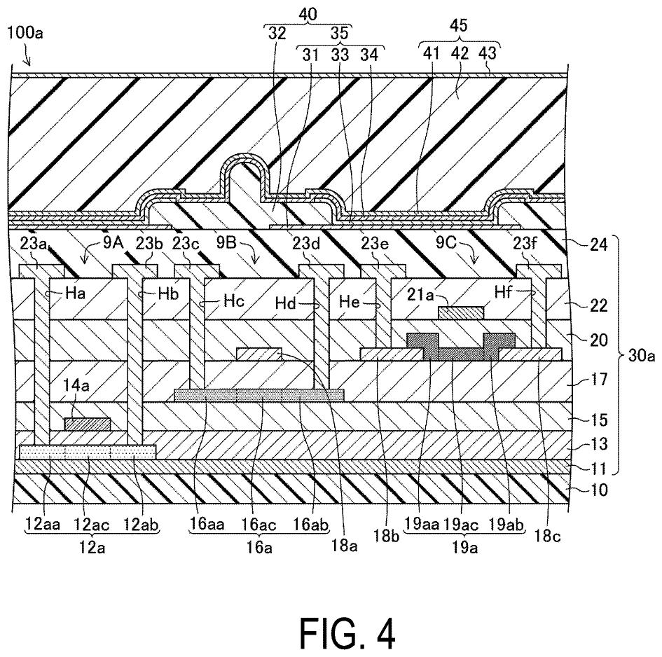

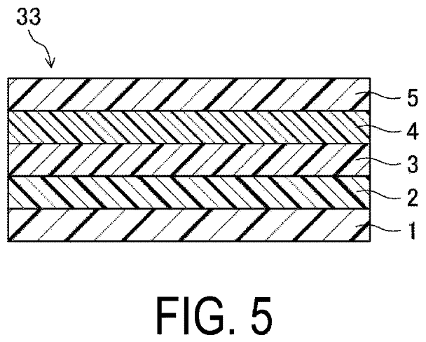

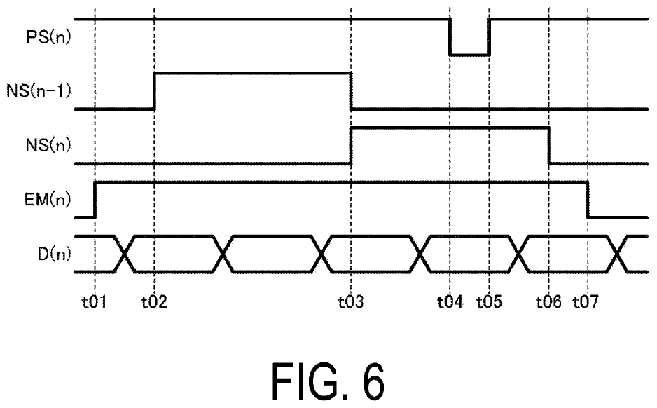

FIGS. 1 to 8 illustrate a first embodiment of a display device according to the disclosure. Note that, in each of the following embodiments, an organic EL display device including an organic EL element layer is exemplified as a display device including a light-emitting element layer. Here, FIG. 1 is a block diagram of an overall configuration of an organic EL display device 100a according to the present embodiment. Further, FIG. 2 is an equivalent circuit diagram of a pixel circuit of a TFT layer 30a constituting the organic EL display device 100a. Further, FIG. 3 is a plan view illustrating a schematic configuration of the TFT layer 30a. Further, FIG. 4 is a cross-sectional view of the organic EL display device 100a. Further, FIG. 5 is a cross-sectional view of an organic EL layer 33 constituting the organic EL display device 100a. Further, FIG. 6 is a timing chart for describing an operation of a pixel circuit of the organic EL display device 100a.

As illustrated in FIG. 1, the organic EL display device 100a is provided with a display region 50 in which a plurality of subpixels P are provided in a matrix shape, and a gate driver 60, an emission driver 70, and a source driver 80 provided in a frame region around the display region 50. Note that, as illustrated in FIG. 1, a display control circuit 150 electrically connected to the gate driver 60, the emission driver 70, and the source driver 80 is provided outside the organic EL display device 100a.

In addition, as illustrated in FIG. 4, the organic EL display device 100a includes a resin substrate 10 provided as a base substrate, the TFT layer 30a provided on the resin substrate 10, an organic EL element layer 40 provided as a light-emitting element layer on the TFT layer 30a, and a sealing film 45 provided on the organic EL element layer 40.

The resin substrate 10 is formed of, for example, a polyimide resin or the like.

As illustrated in FIG. 4, the TFT layer 30a includes a base coat film 11 provided on the resin substrate 10, four first TFTs 9A, one second TFT 9B, two third TFTs 9C, and one capacitor 9h (see FIG. 2) provided on the base coat film 11 for each of subpixels P, and a flattening film 24 provided on the respective first TFTs 9A, second TFTs 9B, third TFTs 9C, and capacitors 9h.

As illustrated in FIG. 1, i pieces of first scanning signal lines PS(1) to PS(i), (i+1) pieces of second scanning signal lines NS(0) to NS(i), i pieces of light emission control lines EM(1) to EM(i), and j pieces of data signal lines D(1) to D(j) are provided in the display region 50 of the TFT layer 30a. Note that each of i and j is an integer equal to or greater than 2, n is an integer in a range from 1 to i, and m is an integer in a range from 1 to j. Further, in FIG. 1, the first scanning signal lines PS, the second scanning signal lines NS, and the data signal lines D are not illustrated in the display region 50. Here, the first scanning signal lines PS(1) to PS(i) are signal lines for transmitting first scanning signals, which are control signals for P-channel type transistors. Further, the second scanning signal lines NS(0) to NS(i) are signal lines for transmitting second scanning signals, which are control signals for N-channel type transistors. Further, the light emission control lines EM(1) to EM(i) are signal lines for transmitting light emission control signals. Note that the first scanning signal lines PS(1) to PS(i), the second scanning signal lines NS(0) to NS(i), and the light emission control lines EM(1) to EM(i) are provided in parallel with each other. Further, the first scanning signal lines PS(1) to PS(i) and the data signal lines D(1) to D(j) are provided to be orthogonal to each other. Further, in a timing chart in FIG. 6, the reference signs PS(1) to PS(i) are also assigned to the first scanning signals supplied to the respective first scanning signal lines PS(1) to PS(i), the reference signs NS(0) to NS(i) are also assigned to the second scanning signals supplied to the respective second scanning signal lines NS(0) to NS(i), the reference signs EM(1) to EM(i) are also assigned to the light emission control signals supplied to the respective light emission control lines EM(1) to EM(i), and the reference signs D(1) to D(j) are also assigned to data signals (data voltages) supplied to the respective data signal lines D(1) to D(j).

Furthermore, a power supply line that supplies a high-level power supply voltage ELVDD (hereinafter, referred to as a “high-level power supply line”) for driving an organic EL element 35, which will be described later, a power supply line that supplies a low-level power supply voltage ELVSS (hereinafter, referred to as a “low-level power supply line”) for driving the organic EL element 35, and a power supply line that supplies an initialization voltage Vini (hereinafter, referred to as an “initialization power supply line”) are provided in the display region 50 of the TFT layer 30a. Note that, in the present embodiment, as necessary, the reference sign ELVDD is also assigned to the high-level power supply line, the reference sign ELVSS is also assigned to the low-level power supply line, and the reference sign Vini is also assigned to the initialization power supply line. The high-level power supply voltage ELVDD, the low-level power supply voltage ELVSS, and the initialization voltage Vini are supplied from a power source circuit that is not illustrated. Here, in the plan view of FIG. 3, a first scanning signal line 14g extending in an X direction is illustrated as a first scanning signal line PS, a light emission control line 14e extending in the X direction is illustrated as the light emission control line EM, a second scanning signal line 18d extending in the X direction is illustrated as the second scanning signal line NS, an initialization power supply line 18i extending in the X direction is illustrated as an initialization power supply line Vini, a data signal line 23g extending in a Y direction is illustrated as the data signal line D, and a high-level power supply line 23h extending in the Y direction is illustrated as the high-level power supply line ELVDD.

Each of the base coat film 11, as will be described later, a first gate insulating film 13 provided as a first inorganic insulating film, a first interlayer insulating film 15 provided as a fourth inorganic insulating film, a second gate insulating film 17 provided as a second inorganic insulating film, a third gate insulating film 20 provided as a third inorganic insulating film, and a second interlayer insulating film 22 provided as a third inorganic insulating film is constituted by a single-layer film of an inorganic insulating film made of, for example, silicon nitride, silicon oxide, silicon oxynitride, or the like, or a layered film thereof. Here, at least a second semiconductor layer 16a side, which will be described later, of the first interlayer insulating film 15, the second semiconductor layer 16a side and a third semiconductor layer 19a side, which will be described later, of the second gate insulating film 17, and the third semiconductor layer 19a side of the third gate insulating film 20 are individually constituted by, for example, a silicon oxide film.

Here, as illustrated in FIG. 4, the first TFT 9A includes a first semiconductor layer 12a provided on the base coat film 11, a first gate electrode 14a provided on the first semiconductor layer 12a with the first gate insulating film 13 interposed therebetween, and a first terminal electrode 23a and a second terminal electrode 23b that are provided on the second interlayer insulating film 22 so as to be separated from each other.

The first semiconductor layer 12a is made of polysilicon, such as Low Temperature PolySilicon (LTPS), for example, and, as illustrated in FIG. 4, includes a first conductor region 12aa and a second conductor region 12ab defined to be separated from each other, and a first channel region 12ac defined between the first conductor region 12aa and the second conductor region 12ab.

As illustrated in FIG. 4, the first gate electrode 14a is provided to overlap the first channel region 12ac of the first semiconductor layer 12a, and is configured to control conduction between the first conductor region 12aa and the second conductor region 12ab of the first semiconductor layer 12a.

As illustrated in FIG. 4, the first terminal electrode 23a and the second terminal electrode 23b are respectively electrically connected to the first conductor region 12aa and the second conductor region 12ab of the first semiconductor layer 12a through a first contact hole Ha and a second contact hole Hb formed in a layered film of the first gate insulating film 13, the first interlayer insulating film 15, the second gate insulating film 17, the third gate insulating film 20, and the second interlayer insulating film 22.

As illustrated in FIG. 4, the second TFT 9B includes the second semiconductor layer 16a provided on the first interlayer insulating film 15, the second gate electrode 18a provided on the second semiconductor layer 16a with the second gate insulating film 17a interposed therebetween, and a third terminal electrode 23c and a fourth terminal electrode 23d provided so as to be separated from each other on the second interlayer insulating film 22. Here, the second TFT 9B has a top contact structure as illustrated in FIG. 4, and a threshold value thereof tends to easily shift to a negative side.

The second semiconductor layer 16a is made of, for example, an In—Ga—Zn—O based oxide semiconductor, and includes, as illustrated in FIG. 4, a third conductor region 16aa and a fourth conductor region 16ab defined so as to be separated from each other, and a second channel region 16ac defined between the third conductor region 16aa and the fourth conductor region 16ab. Here, the In—Ga—Zn—O based semiconductor is a ternary oxide of indium (In), gallium (Ga), and zinc (Zn), and a ratio (a composition ratio) of In, Ga, and Zn is not particularly limited to specific values. The In—Ga—Zn—O based semiconductor may be an amorphous semiconductor or may be a crystalline semiconductor. Note that as a crystalline In—Ga—Zn—O based semiconductor, a crystalline In—Ga—Zn—O based semiconductor in which the c-axis is oriented substantially perpendicular to the layer surface is preferable. In place of the In—Ga—Zn—O based semiconductor, another oxide semiconductor may be included. Examples of the other oxide semiconductor may include an In—Sn—Zn—O based semiconductor (for example, In₂O₃—SnO₂—ZnO; InSnZnO). Here, the In—Sn—Zn—O based semiconductor is a ternary oxide of indium (In), tin (Sn), and zinc (Zn). Alternatively, examples of the other oxide semiconductor may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), a Mg—Zn—O based semiconductor, an In—Ga—Sn—O based semiconductor, an In—Ga—O based semiconductor, a Z—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, InGaO₃(ZnO)₅, magnesium zinc oxide (MgₓZn₁₋ₓO), and cadmium zinc oxide (CdₓZn₁₋ₓO). Note that, as the Zn—O based semiconductor, a semiconductor in a non-crystalline (amorphous) state of ZnO to which one kind or a plurality of kinds of impurity elements among group 1 elements, group 13 elements, group 14 elements, group 15 elements, group 17 elements, and the like are added, a semiconductor in a polycrystalline state, a semiconductor in a microcrystalline state in which the non-crystalline state and the polycrystalline state are mixed, or a semiconductor to which no impurity element is added can be used.

As illustrated in FIG. 4, the second gate electrode 18a is provided so as to be superimposed over the second channel region 16ac of the second semiconductor layer 16a, and is configured to control conduction between the third conductor region 16aa and the fourth conductor region 16ab of the second semiconductor layer 16a.

As illustrated in FIG. 4, the third terminal electrode 23c and the fourth terminal electrode 23d are respectively electrically connected to the third conductor region 16aa and the fourth conductor region 16ab of the second semiconductor layer 16a through a third contact hole Hc and a fourth contact hole Hd formed in a layered film of the second gate insulating film 17, the third gate insulating film 20, and the second interlayer insulating film 22.

Further, as illustrated in FIG. 4, the third TFT 9C includes a third semiconductor layer 19a provided on the second gate insulating film 17, a first relay electrode 18b and a second relay electrode 18c provided on the resin substrate 10 side of the third semiconductor layer 19a so as to be separated from each other, a third gate electrode 21a provided on the third semiconductor layer 19a with the third gate insulating film 20 interposed therebetween, and a fifth terminal electrode 23e and a sixth terminal electrode 23f provided on the second interlayer insulating film 22 so as to be separated from each other. Here, as illustrated in FIG. 4, the third TFT 9C has a bottom contact structure, and the threshold value thereof tends to easily shift to a positive side due to oxidation of the oxide semiconductor caused by oxygen ashing during patterning a second metal film, which will be described later, by dry etching or a small amount of residue of the second metal film, for example, in order to form the first relay electrode 18b and the second relay electrode 18c.

Similarly to the second semiconductor layer 16a, the third semiconductor layer 19a is made of an oxide semiconductor such as an In—Ga—Zn—O based semiconductor or the like, for example, and, as illustrated in FIG. 4, includes a fifth conductor region 19aa and a sixth conductor region 19ab defined so as to be separated from each other, and a third channel region 19ac defined between the fifth conductor region 19aa and the sixth conductor region 19ab.

As illustrated in FIG. 4, the first relay electrode 18b and the second relay electrode 18c are provided on the second gate insulating film 17 so as to be in contact with lower surfaces of the fifth conductor region 19aa and the sixth conductor region 19ab of the third semiconductor layer 19a, respectively.

As illustrated in FIG. 4, the third gate electrode 21a is provided so as to be superimposed over the third channel region 19ac of the third semiconductor layer 19a, and is configured to control conduction between the fifth conductor region 19aa and the sixth conductor region 19ab of the third semiconductor layer 19a.

As illustrated in FIG. 4, the fifth terminal electrode 23e and the sixth terminal electrode 23f are respectively electrically connected to the first relay electrode 18b and the second relay electrode 18c through a fifth contact hole He and a sixth contact hole Hf formed in a layered film of the third gate insulating film 20 and the second interlayer insulating film 22.

Note that, as illustrated in FIG. 4, in the TFT layer 30a, the base coat film 11, a first semiconductor film serving as the first semiconductor layer 12a and the like, the first gate insulating film 13, a first metal film serving as the first gate electrode 14a and the like, the first interlayer insulating film 15, a second semiconductor film serving as the second semiconductor layer 16a and the like, the second gate insulating film 17, a second metal film serving as the first relay electrode 18b and the like, a third semiconductor film serving as the third semiconductor layer 19a and the like, the third gate insulating film 20, a third metal film serving as the third gate electrode 21a and the like, the second interlayer insulating film 22, a fourth metal film serving as the first terminal electrode 23a and the like, and the flattening film 24 are sequentially layered on the resin substrate 10.

In the present embodiment, a write control TFT 9c, a drive TFT 9d, a power supply control TFT 9e, and a light emission control TFT 9f, which will be described later, are provided as the first TFT 9A, a threshold voltage compensation TFT 9b, which will be described later, is provided as the second TFT 9B, and an initialization TFT 9a and an anode discharge TFT 9g, which will be described later, are provided as the third TFT 9C (see FIG. 2). Note that, in the equivalent circuit diagram illustrated in FIG. 2, a first terminal electrode 23a and a second terminal electrode 23b of each of the write control TFT 9c, the drive TFT 9d, the power supply control 9e, and the light emission control TFT 9f are indicated by circled numbers 1 and 2, a third terminal electrode 23c and a fourth terminal electrode 23d of the threshold voltage compensation TFT 9b are indicated by circled numbers 3 and 4, and a fifth terminal electrode 23e and a sixth terminal electrode 23f of each of the initialization TFT 9a and the anode discharge TFT 9g are indicated by circled numbers 5 and 6.

As illustrated in FIG. 2, the initialization TFT 9a includes the third gate electrode 21a electrically connected to the second scanning signal line NS(n-1) in an (n-1)-th row, the fifth terminal electrode 23e connected to the third terminal electrode 23c of the threshold voltage compensation TFT 9b, the first gate electrode 14a and the capacitor 9h of the drive TFT 9d, and the sixth terminal electrode 23f electrically connected to the initialization power supply line Vini.

As illustrated in FIG. 2, the threshold voltage compensation TFT 9b includes the second gate electrode 18a electrically connected to the second scanning signal line NS in an n-th row, the third terminal electrode 23c electrically connected to the fifth terminal electrode 23e of the initialization TFT 9a, the first gate electrode 14a of the drive transistor 9d, and the capacitor 9h, and the fourth terminal electrode 23d electrically connected to the second terminal electrode 23b of the drive TFT 9d and the first terminal electrode 23a of the light emission control TFT 9f.

As illustrated in FIG. 2, the write control TFT 9c includes the first gate electrode 14a electrically connected to the first scanning signal line PS(n) in the n-th row, the first terminal electrode 23a electrically connected to the data signal line D(m) in an m-th column, and the second terminal electrode 23b electrically connected to the first terminal electrode 23a of the drive TFT 9d and the second terminal electrode 23b of the power supply control TFT 9e.

As illustrated in FIG. 2, the drive TFT 9d includes the first gate electrode 14a electrically connected to the fifth terminal electrode 23e of the initialization TFT 9a, the third terminal electrode 23c of the threshold voltage compensation TFT 9b and the capacitor 9h, the first terminal electrode 23a electrically connected to the second terminal electrode 23b of the write control TFT 9c and the second terminal electrode 23b of the power supply control TFT 9e, and the second terminal electrode 23b electrically connected to the fourth terminal electrode 23d of the threshold voltage compensation TFT 9b and the first terminal electrode 23a of the light emission control TFT 9f. Note that the high-level power supply voltage ELVDD is input to the first terminal electrode 23a of the drive TFT 9d during a period in which an organic EL element 35 emits light, and the data signal D(m) is input to the first terminal electrode 23a of the drive TFT 9d during a period in which writing to the capacitor 9h is performed.

As illustrated in FIG. 2, the power supply control TFT 9e includes the first gate electrode 14a electrically connected to the light emission control line EM(n) in the n-th row, the first terminal electrode 23a electrically connected to the high-level power supply line ELVDD and the capacitor 9h, and the second terminal electrode 23b electrically connected to the second terminal electrode 23b of the write control TFT 9c and the first terminal electrode 23a of the drive TFT 9d.

As illustrated in FIG. 2, the light emission control TFT 9f includes the first gate electrode 14a electrically connected to the light emission control line EM(n) in the n-th row, the first terminal electrode 23a electrically connected to the fourth terminal electrode 23d of the threshold voltage compensation TFT 9b and the second terminal electrode 23b of the drive TFT 9d, and the second terminal electrode 23b electrically connected to the sixth terminal electrode 23f of the anode discharge TFT 9g and the first electrode 31, which will be described later, of the organic EL element 35.

As illustrated in FIG. 2, the anode discharge TFT 9g includes the third gate electrode 21a electrically connected to the light emission control line EM(n) in the n-th row, the fifth terminal electrode 23e electrically connected to the initialization power supply line Vini, and the sixth terminal electrode 23f electrically connected to the second terminal electrode 23b of the light emission control TFT 9f and the first electrode 31 of the organic EL element 35.

The capacitor 9h includes, for example, a first capacitance electrode made of the same material as the third gate electrode 21a and provided in the same layer as the third gate electrode 21a, a second capacitance electrode made of the same material as the first terminal electrode 23a and provided in the same layer as the first terminal electrode 23a, and the second interlayer insulating film 22 provided between the first capacitance electrode and the second capacitance electrode. Here, the capacitor 9h includes the first capacitance electrode electrically connected to the high-level power supply line ELVDD and the first terminal electrode 23a of the power supply control TFT 9e, and the second capacitance electrode electrically connected to the fifth terminal electrode 23e of the initialization TFT 9a, the third terminal electrode 23c of the threshold voltage compensation TFT 9b, and the first gate electrode 14a of the drive TFT 9d.

The flattening film 24 has a flat surface in the display region 50, and is made of, for example, an organic resin material such as a polyimide resin or an acrylic resin, or a polysiloxane-based Spin On Glass (SOG) material.

As illustrated in FIG. 4, the organic EL element layer 40 includes a plurality of the organic EL elements 35 provided as a plurality of light-emitting elements arrayed in a matrix shape in correspondence with the plurality of subpixels P, and an edge cover 32 provided in a lattice pattern shared by all the subpixels P so as to cover peripheral edge portions of the first electrode 31, which will be described later, of each of the organic EL elements 35.

As illustrated in FIG. 4, the organic EL element 35 includes, in each of the subpixels P, the first electrode 31 (anode electrode) provided on the flattening film 24 of the TFT layer 30a, the organic EL layer 33 provided on the first electrode 31, and a second electrode 34 (cathode electrode) provided on the organic EL layer 33.

The first electrode 31 is electrically connected to the second terminal electrode 23b of the light emission control TFT 9f of each of the subpixels P, through a contact hole formed in the flattening film 24. Further, the first electrode 31 functions to inject holes (positive holes) into the organic EL layer 33. Further, the first electrode 31 is preferably made of a material having a high work function to improve the efficiency of hole injection into the organic EL layer 33. Here, examples of materials constituting the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Further, examples of the materials constituting the first electrode 31 may be an alloy such as astatine (At)/astatine oxide (AtO2). Furthermore, examples of the materials constituting the first electrode 31 may include electrically conductive oxide such as tin oxide (SnO), zinc oxide (ZnO), indium tin oxide (ITO), and indium zinc oxide (IZO). Additionally, the first electrode 31 may be formed by layering a plurality of layers made of any of the materials described above. Note that examples of compound materials having a high work function include indium tin oxide (ITO) and indium zinc oxide (IZO).

As illustrated in FIG. 5, the organic EL layer 33 includes a hole injection layer 1, a hole transport layer 2, a light-emitting layer 3, an electron transport layer 4, and an electron injection layer 5, which are sequentially layered on the first electrode 31.

The hole injection layer 1 is also referred to as an anode electrode buffer layer, and functions to reduce an energy level difference between the first electrode 31 and the organic EL layer 33, thereby improving the efficiency of hole injection into the organic EL layer 33 from the first electrode 31. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 functions to improve the efficiency of hole transport from the first electrode 31 to the organic EL layer 33. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons are injected from the first electrode 31 and the second electrode 34, respectively, and the holes and the electrons recombine in a case where a voltage is applied via the first electrode 31 and the second electrode 34. Here, the light-emitting layer 3 is made of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of causing electrons to efficiently migrate to the light-emitting layer 3. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 functions to reduce an energy level difference between the second electrode 34 and the organic EL layer 33, thereby improving the efficiency of electron injection into the organic EL layer 33 from the second electrode 34, and this function allows the drive voltage of the organic EL element 35 to be reduced. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 4, the second electrode 34 is provided in common to all of the subpixels P so as to cover each of the organic EL layers 33 and the edge cover 32. Further, the second electrode 34 functions to inject electrons into the organic EL layer 33. Further, the second electrode 34 is preferably formed of a material having a low work function to improve the efficiency of electron injection into the organic EL layer 33. Further, as illustrated in FIG. 2, the second electrode 34 is electrically connected to the low-level power supply line ELVSS. Here, examples of a material constituting the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may be formed of an alloy, such as magnesium (Mg)/copper (Cu), magnesium (Mg)/silver (Ag), sodium (Na)/potassium (K), astatine (At)/astatine oxide (AtO2), lithium (Li)/aluminum (Al), lithium (Li)/calcium (Ca)/aluminum (Al), and lithium fluoride (LiF)/calcium (Ca)/aluminum (Al). Further, the second electrode 34 may be formed of an electrically conductive oxide such as tin oxide (SnO), zinc oxide (ZnO), indium tin oxide (ITO), and indium zinc oxide (IZO). Further, the second electrode 34 may be formed by layering a plurality of layers formed of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The edge cover 32 is made of, for example, an organic resin material such as a polyimide resin or an acrylic resin, or an SOG material of a polysiloxane based.

As illustrated in FIG. 4, the sealing film 45 is provided covering the second electrode 34, includes a first inorganic sealing film 41, an organic sealing film 42, and a second inorganic sealing film 43 layered sequentially in this order on the second electrode 34, and functions to protect the organic EL layer 33 of the organic EL element 35 from moisture and oxygen.

The first inorganic sealing film 41 and the second inorganic sealing film 43 are constituted of, for example, an inorganic insulating film such as a silicon nitride film, a silicon oxide film, or a silicon oxynitride film.

The organic sealing film 42 is made of, for example, an organic resin material such as an acrylic resin, an epoxy resin, a silicone resin, a polyurea resin, a parylene resin, a polyimide resin, or a polyamide resin.

Next, an operation of the organic EL display device 100a having the above-described configuration will be described.

### Operation of Peripheral Circuit

As illustrated in FIG. 1, the display control circuit 150 receives an input image signal DIN and a timing signal group (a horizontal synchronization signal, a vertical synchronization signal, and the like) TG transmitted from the outside, and outputs a digital video signal DV, a gate control signal GCTL for controlling the operation of the gate driver 60, an emission driver control signal EMCTL for controlling the operation of the emission driver 70, and a source control signal SCTL for controlling the operation of the source driver 80. Here, the gate control signal GCTL includes a gate start pulse signal, a gate clock signal, and the like. Further, the emission driver control signal EMCTL includes an emission start pulse signal, an emission clock signal, and the like. Further, the source control signal SCTL includes a source start pulse signal, a source clock signal, a latch strobe signal, and the like.

The gate driver 60 is electrically connected to the first scanning signal lines PS(1) to PS(i) and the second scanning signal lines NS(0) to NS(i). Then, based on the gate control signal GCTL output from the display control circuit 150, the gate driver 60 applies the first scanning signal to the first scanning signal lines PS(1) to PS(i), and the second scanning signal to the second scanning signal lines NS(0) to NS(i).

The emission driver 70 is electrically connected to the light emission control lines EM(1) to EM(i). Then, based on the emission driver control signal EMCTL output from the display control circuit 150, the emission driver 70 applies the light emission control signal to the light emission control lines EM(1) to EM(i).

The source driver 80 includes a j-bit shift register, a sampling circuit, a latch circuit, j pieces of D/A converters, and the like, which are not illustrated. Here, the shift register includes j pieces of cascade-connected registers, and based on the source clock signal, the shift register sequentially transfers a pulse of the source start pulse signal supplied to a first stage register from an input end to an output end, and a sampling pulse is output from the register of each stage according to the transfer of the pulse. Then, the sampling circuit stores the digital video signal DV based on the sampling pulse. Then, in accordance with the latch strobe signal, the latch circuit acquires and holds the digital video signal DV for one row stored in the sampling circuit. Then, the D/A converter is provided corresponding to each of the data signal lines D(1) to D(j), converts the digital video signal DV held in the latch circuit to an analog voltage, and applies the converted analog voltage as a data signal (data voltage) to all the data signal lines D(1) to D(j) simultaneously.

As described above, as a result of the data signal being applied to the data signal lines D(1) to D(j), the first scanning signal being applied to the first scanning signal lines PS(1) to PS(i), the second scanning signal being applied to the second scanning signal lines NS(0) to NS(i), and the light emission control signal being applied to the light emission control lines EM(1) to EM(i), an image based on the input image signal DIN is displayed in the display region 50.

### Operation of Pixel Circuit

Next, an operation of the pixel circuit of the organic EL display device 100a according to the present embodiment will be described using the timing chart in FIG. 6. Note that the operation of the pixel circuit described here is merely an example, and no limitation thereto is intended.

First, before a time t01, the first scanning signal PS(n) is at a high level, and the second scanning signal NS(n-1), the second scanning signal NS(n), and the light emission control signal EM(n) are at a low level. At this time, the power supply control TFT 9e and the light emission control TFT 9f are in an on state, and the anode discharge TFT 9g is in an off state. Accordingly, before the time t01, a drive current corresponding to a charging voltage of the capacitor 9h is supplied to the organic EL element 35, and the organic EL element 35 emits light according to the magnitude of the drive current.

At the time t01, as a result of the light emission control signal EM(n) changing from the low level to the high level, the power supply control TFT 9e and the light emission control TFT 9f are in the off state. As a result, the supply of the drive current to the organic EL element 35 is cut off, and the organic EL element 35 is thus in an unlighted state. Further, as a result of the light emission control signal EM(n) changing from the low level to the high level, the anode discharge TFT 9g turns on. Thus, the voltage of the first electrode 31 of the organic EL element 35 is initialized based on the initialization voltage Vini.

At a time t02, as a result of the second scanning signal NS(n-1) changing from the low level to the high level, the initialization TFT 9a turns on. As a result, the gate voltage of the drive TFT 9d is initialized. In other words, the gate voltage of the drive TFT 9d becomes equal to the initialization voltage Vini.

At a time t03, as a result of the second scanning signal NS(n-1) changing from the high level to the low level, the initialization TFT 9a turns off. Further, at the time t03, the second scanning signal NS(n) changes from the low level to the high level. Thus, the threshold voltage compensation TFT 9b turns on.

At a time t04, as a result of the first scanning signal PS(n) changing from the high level to the low level, the write control TFT 9c turns on. Here, the threshold voltage compensation TFT 9b has been in the on state since the time t03, and thus when the write control TFT 9c turns on at the time t04, the data signal D(m) is input to the second capacitance electrode of the capacitor 9h via the write control TFT 9c, the drive TFT 9d, and the threshold voltage compensation TFT 9b. In this way, the capacitor 9h is charged.

At a time t05, as a result of the first scanning signal PS(n) changing from the low level to the high level, the write control TFT 9c turns off.

At a time t06, as a result of the second scanning signal NS(n) changing from the high level to the low level, the threshold voltage compensation TFT 9b turns off.

At a time t07, as a result of the light emission control signal EM(n) changing from the high level to the low level, the anode discharge TFT 9g turns off, and, at the same time, the power supply control TFT 9e and the light emission control TFT 9f turn on. In this way, the drive current corresponding to the charging voltage of the capacitor 9h is supplied to the organic EL element 35, and thus the organic EL element 35 emits light according to the magnitude of the drive current.

Thus, in the organic EL display device 100a, the organic EL element 35 in each subpixel P emits light with a luminance corresponding to the drive current, and an image is displayed.

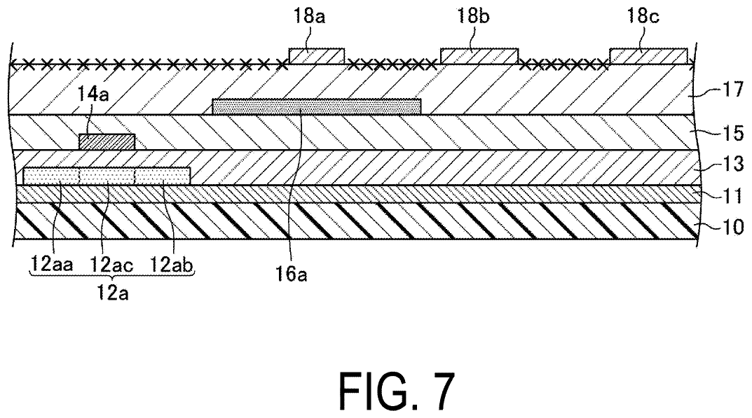

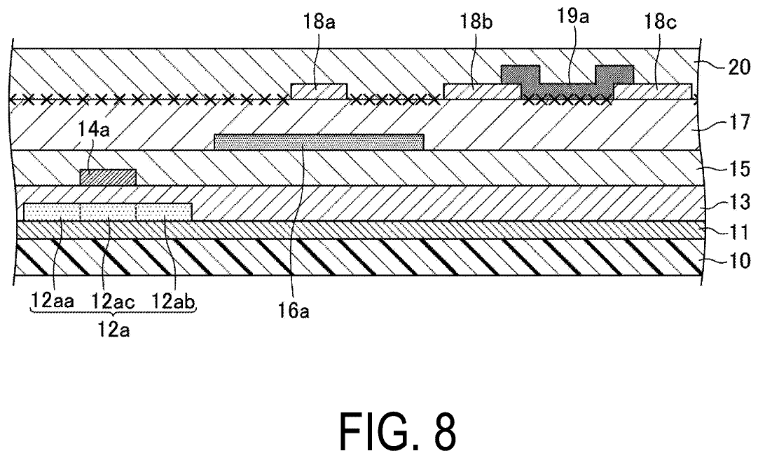

Next, a manufacturing method for the organic EL display device 100a according to the present embodiment will be described. Note that the manufacturing method for the organic EL display device 100a includes TFT layer forming, organic EL element layer forming, and sealing film forming. Here, FIG. 7 is a cross-sectional view illustrating a part of forming the TFT layer 30a. Further, FIG. 8 is a cross-sectional view illustrating a part of forming the TFT layer 30a subsequent to the process illustrated in FIG. 7.

### TFT Layer Forming

First, for example, a silicon oxide film (having a thickness of approximately 100 nm) is formed, for example, by plasma Chemical Vapor Deposition (CVD), on the resin substrate 10 formed on a glass substrate, thereby forming the base coat film 11.

Subsequently, an amorphous silicon film (having a thickness of about 50 nm) is formed, for example, by plasma CVD on the substrate surface on which the base coat film 11 is formed, the amorphous silicon film is crystallized by laser annealing or the like to form the first semiconductor film made of polysilicon, and then the first semiconductor film is patterned to form the first semiconductor layer 12a and the like.

After that, a silicon oxide film (having a thickness of about 100 nm) is formed, for example, by plasma CVD on the substrate surface on which the first semiconductor layer 12a and the like are formed, to form the first gate insulating film 13.

Furthermore, a first metal film is formed by forming a molybdenum film (having a thickness of approximately 250 nm) or the like by, for example, sputtering on the substrate surface on which the first gate insulating film 13 is formed, and then, the first metal film is patterned to form the first gate electrode 14a, the first scanning signal line 14g, the light emission control line 14e, and the like.

Subsequently, by using the first gate electrode 14a as a mask and doping with impurity ions, a part of the first semiconductor layer 12a is caused to be conductive, and the first conductor region 12aa, the second conductor region 12ab, and the first channel region 12ac are formed in the first semiconductor layer 12a.

After that, a single-layer film of a silicon oxide film (having a thickness of about 200 nm), or a layered film in which a silicon nitride film (having a thickness of about 150 nm) and a silicon oxide film (having a thickness of about 50 nm) are sequentially layered is formed, for example, by plasma CVD, on the substrate surface on which the part of the first semiconductor layer 12a is made conductive, to form the first interlayer insulating film 15.

Further, a second semiconductor film made of an oxide semiconductor is formed by forming a film of InGaZnO₄ and the like (having a thickness of about 30 nm) by, for example, sputtering, on the substrate surface on which the first interlayer insulating film 15 is formed, and then, the second semiconductor film is patterned to form the second semiconductor layer 16a and the like.

Subsequently, a silicon oxide film (having a thickness of approximately 100 nm) is formed by, for example, plasma CVD, on the substrate surface where the second semiconductor layer 16a and the like are formed, thereby forming the second gate insulating film 17.

After that, a second metal film is formed by forming a molybdenum film and the like (having a thickness of approximately 250 nm) by sputtering, for example, on the substrate surface on which the second gate insulating film 17 is formed, and then, the second metal film is patterned to form the second gate electrode 18a, the first relay electrode 18b, the second relay electrode 18c, the second scanning signal line 18d, the initialization power supply line 18i and the like, as illustrated in FIG. 7. At this time, on the surface of the second gate insulating film 17 exposed from the second gate electrode 18a, the first relay electrode 18b, the second relay electrode 18c, the second scanning signal line 18d, the initialization power supply line 18i, and the like, as indicated by x marks in FIG. 7, oxygen is adsorbed due to oxygen ashing during dry etching and oxygen adsorbed on residue of the second metal film.

Subsequently, a third semiconductor film made of an oxide semiconductor is formed by forming a film of InGaZnO₄ and the like (having a thickness of about 30 nm) by, for example, sputtering on the substrate surface on which the second gate electrode 18a and the like are formed, and then, the third semiconductor film is patterned to form the third semiconductor layer 19a and the like. At this time, the third semiconductor layer 19a is oxidized by diffusion of oxygen from the surface of the second gate insulating film 17 (see FIG. 8).

Subsequently, a silicon oxide film (having a thickness of approximately 100 nm) is formed by, for example, plasma CVD, on the substrate surface where the third semiconductor layer 19a and the like are formed, thereby forming the third gate insulating film 20 as illustrated in FIG. 8.

After that, on the substrate surface on which the third gate insulating film 20 is formed, a single-layer film of a molybdenum film (having a thickness of about 250 nm), a layered film in which an aluminum film (having a thickness of about 300 nm) and a titanium film (having a thickness of about 50 nm) are sequentially layered, a layered film in which a titanium film (having a thickness of about 50 nm), an aluminum film (having a thickness of about 300 nm), and a titanium film (having a thickness of about 50 nm) are sequentially layered, or the like is formed by, for example, sputtering to form a third metal film, and then the third metal film is patterned to form the third gate electrode 21a and the like.

Further, on the substrate surface on which the third gate electrode 21a and the like are formed, a silicon oxide film (having a thickness of about 300 nm) and a silicon nitride film (having a thickness of about 150 nm) are sequentially formed by, for example, plasma CVD, thereby forming the second interlayer insulating film 22. Note that, by performing heat treatment after forming the second interlayer insulating film 22, a part of the second semiconductor layer 16a and a part of the third semiconductor layer 19a are caused to be conductive, and the third conductor region 16aa, the fourth conductor region 16ab, and the second channel region 16ac are formed in the second semiconductor layer 16a, and the fifth conductor region 19aa, the sixth conductor region 19ab, and the third channel region 19ac are formed in the third semiconductor layer 19a.

Thereafter, at the substrate surface where the second interlayer insulating film 22 is formed, the first gate insulating film 13, the first interlayer insulating film 15, the second gate insulating film 17, the third gate insulating film 20, and the second interlayer insulating film 22 are appropriately patterned to form the first contact hole Ha, the second contact hole Hb, the third contact hole Hc, the fourth contact hole Hd, the fifth contact hole He, and the sixth contact hole Hf.

Furthermore, a fourth metal film is formed by sequentially forming a titanium film (having a thickness of approximately 50 nm), an aluminum film (having a thickness of approximately 400 nm), a titanium film (having a thickness of approximately 50 nm) and the like by sputtering, for example, on the substrate surface at which the first contact hole Ha and the like is formed, and then, the fourth metal film is patterned to form the first terminal electrode 23a, the second terminal electrode 23b, the third terminal electrode 23c, the fourth terminal electrode 23d, the fifth terminal electrode 23e, the sixth terminal electrode 23f, the data signal line 23g, the high-level power supply line 23h, and the like.

Finally, after applying a polyimide-based photosensitive resin film (having a thickness of about 2 μm) to the substrate surface on which the first terminal electrode 23a and the like are formed, by spin coating or slit coating, for example, pre-baking, exposing, developing, and post-baking are performed on the applied film to form the flattening film 24.

As described above, the TFT layer 30a can be formed.

### Organic EL Element Layer Forming

The organic EL element layer 40 is formed by forming, using a known method, the first electrode 31, the edge cover 32, the organic EL layer 33, and the second electrode 34 on the flattening film 24 of the TFT layer 30a that has been formed in the TFT layer forming.

### Sealing Film Forming

First, an inorganic insulating film such as a silicon nitride film, a silicon oxide film, or a silicon oxynitride film is formed by plasma CVD on the substrate surface formed with the organic EL element layer 40 formed in the organic EL element layer forming described above by using a mask to form the first inorganic sealing film 41.

Next, on the substrate surface on which the first inorganic sealing film 41 is formed, a film made of an organic resin material such as an acrylic resin is formed by, for example, using an ink-jet method to form the organic sealing film 42.

Thereafter, an inorganic insulating film such as a silicon nitride film, a silicon oxide film, or a silicon oxynitride film is formed by plasma CVD on the substrate surface formed with the organic sealing film 42 by using a mask to form the second inorganic sealing film 43, thereby forming the sealing film 45.

Finally, after a protective sheet (not illustrated) is applied to the substrate surface formed with the sealing film 45, the glass substrate is peeled off from the lower face of the resin substrate 10 by irradiation with laser light from the glass substrate side of the resin substrate 10, and then a protective sheet (not illustrated) is applied to the lower face of the resin substrate 10, from which the glass substrate has been peeled off.

The organic EL display device 100a according to the present embodiment can be manufactured as described above.

As described above, according to the organic EL display device 100a of the present embodiment, the threshold voltage compensation TFT 9b provided as the second TFT 9B has the top contact structure, and the initialization TFT 9a and the anode discharge TFT 9g provided as the third TFT 9C have the bottom contact structure. Here, in the initialization TFT 9a and the anode discharge TFT 9g having the bottom contact structure, when the first relay electrode 18b and the second relay electrode 18c are formed, oxygen is adsorbed on the surface of the second gate insulating film 17. Thus, the third semiconductor layer 19a formed thereafter is oxidized. This causes a margin in the off state to be sufficiently ensured in each of the initialization TFT 9a and the anode discharge electrode TFT 9g because threshold values of the initialization TFT 9a and the anode discharge TFT 9g are likely to go to the positive side. Note that when the light emission control signal EM(n) is at the low level, the light emission control TFT 9f is in the on state and a current flows through the organic EL device 35 to emit light. However, in a case where the anode discharge TFT 9g does not sufficiently enter the off state at this time, the current to flow through the organic EL element 35 flows through the initialization power supply line Vini, and the threshold value of the anode discharge TFT 9g also goes to the positive side, thereby sufficiently ensuring the off margin. On the other hand, in the threshold voltage compensation TFT 9b having the top contact structure, when the first relay electrode 18b and the second relay electrode 18c are formed, the second semiconductor layer 16a is not oxidized and the threshold value of the second TFT 9B easily shifts to the negative side. Thus, the voltage of the data signal can be sufficiently written to the first gate electrode 14a of the drive TFT 9d. As a result, in the organic EL display device 100a having the hybrid structure including the first TFT 9A using polysilicon and the second TFT 9B and the third TFT 9C using the oxide semiconductor, characteristics of the second TFT 9B and the third TFT 9C using the oxide semiconductor can be appropriately adjusted.

### Second Embodiment

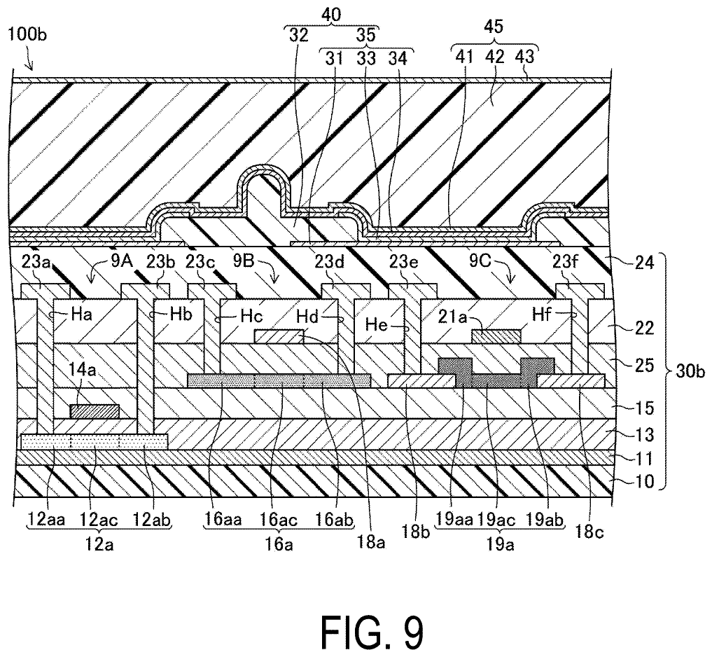

FIG. 9 to FIG. 12 illustrate a second embodiment of a display device according to the disclosure. Here, FIG. 9 is a cross-sectional view of an organic EL display device 100b according to the present embodiment. Note that, in each of the following embodiments, the same portions as those in FIG. 1 to FIG. 8 are denoted by the same reference signs, and a detailed description of these portions is omitted.

In the first embodiment described above, the organic EL display device 100a including the TFT layer 30a in which the second semiconductor layer 16a of the second TFT 9B is provided on the resin substrate 10 side relative to the third semiconductor layer 19a of the third TFT 9C has been exemplified, while in the present embodiment, the organic EL display device 100b including a TFT layer 30b in which the second semiconductor layer 16a of the second TFT 9B and the third semiconductor layer 19a of the third TFT 9C are provided using the same material in the same layer is exemplified.

Similarly to the organic EL display device 100a in the first embodiment described above, the organic EL display device 100b includes the display region 50 in which a plurality of subpixels P are provided in a matrix shape, and the gate driver 60, the emission driver 70, and the source driver 80 provided in a frame region around the display region 50. Note that a display control circuit 150 electrically connected to the gate driver 60, the emission driver 70, and the source driver 80 is provided outside the organic EL display device 100b, similarly to the organic EL display device 100a in the first embodiment.

Additionally, as illustrated in FIG. 9, the organic EL display device 100b includes the resin substrate 10 provided as a base substrate, the TFT layer 30b provided on the resin substrate 10, the organic EL element layer 40 provided on the TFT layer 30b as a light-emitting element layer, and the sealing film 45 provided on the organic EL element layer 40.

As illustrated in FIG. 9, the TFT layer 30b includes the base coat film 11 provided on the resin substrate 10, four first TFTs 9A, one second TFT 9B, two third TFTs 9C, and one capacitor 9h provided on the base coat film 11 for each subpixel P, and the flattening film 24 provided on the respective first TFTs 9A, second TFTs 9B, third TFTs 9C, and capacitors 9h.

In the display region 50 of the TFT layer 30b, i pieces of first scanning signal lines PS(1) to PS(i), (i+1) pieces of second scanning signal lines NS(0) to NS(i), i pieces of light emission control lines EM(1) to EM(i), j pieces of data signal lines D(1) to D(j), a high-level power supply line ELVDD, a low-level power supply line ELVSS, and an initialization power supply line Vini are provided, similarly to the TFT layer 30a in the first embodiment.

As illustrated in FIG. 9, the first terminal electrode 23a and the second terminal electrode 23b of the first TFT 9A are respectively electrically connected to the first conductor region 12aa and the second conductor region 12ab of the first semiconductor layer 12a through a first contact hole Ha and a second contact hole Hb formed in a layered film of the first gate insulating film 13, the first interlayer insulating film 15, the common gate insulating film 25, and the second interlayer insulating film 22.

As illustrated in FIG. 9, the second TFT 9B includes the second semiconductor layer 16a provided on the first interlayer insulating film 15, the second gate electrode 18a provided on the second semiconductor layer 16a with the common gate insulating film 25 interposed therebetween, and the third terminal electrode 23c and the fourth terminal electrode 23d provided so as to be separated from each other on the second interlayer insulating film 22. Here, the second TFT 9B has a top contact structure as illustrated in FIG. 9, and the threshold value thereof tends to easily shift to a negative side. Note that the common gate insulating film 25 is provided as a common inorganic insulating film that serves as a second inorganic insulating film, ensuring electrical insulation between the second semiconductor layer 16a and the second gate electrode 18a and that also serves as a third inorganic insulating film ensuring electrical insulation between the third semiconductor layer 19a and the third gate electrode 21a.

As illustrated in FIG. 9, the third terminal electrode 23c and the fourth terminal electrode 23d are respectively electrically connected to the third conductor region 16aa and the fourth conductor region 16ab of the second semiconductor layer 16a through a third contact hole Hc and a fourth contact hole Hd formed in a layered film of the common gate insulating film 25 and the second interlayer insulating film 22.

As illustrated in FIG. 9, the third TFT 9C includes the third semiconductor layer 19a provided on the first interlayer insulating film 15, the first relay electrode 18b and the second relay electrode 18c provided on the resin substrate 10 side of the third semiconductor layer 19a so as to be separated from each other, the third gate electrode 21a provided on the third semiconductor layer 19a with the common gate insulating film 25 interposed therebetween, and the fifth terminal electrode 23e and the sixth terminal electrode 23f provided so as to be separated from each other on the second interlayer insulating film 22. Here, as illustrated in FIG. 9, the third TFT 9C has a bottom contact structure, and for example, when a second metal film is patterned by dry etching to form the first relay electrode 18b and the second relay electrode 18c, the oxide semiconductor is oxidized by oxygen ashing or a small amount of residue of the second metal film, and thus the threshold value thereof tends to easily shift to a positive side.

As illustrated in FIG. 9, the first relay electrode 18b and the second relay electrode 18c are provided on the first interlayer insulating film 15 and are provided so as to be in contact with the lower surfaces of the fifth conductor region 19aa and the sixth conductor region 19ab of the third semiconductor layer 19a, respectively.

As illustrated in FIG. 9, the fifth terminal electrode 23e and the sixth terminal electrode 23f are respectively electrically connected to the first relay electrode 18b and the second relay electrode 18c through a fifth contact hole He and a sixth contact hole Hf formed in the layered film of the common gate insulating film 25 and the second interlayer insulating film 22.

Note that, as illustrated in FIG. 9, in the TFT layer 30b, the base coat film 11, a first semiconductor film serving as the first semiconductor layer 12a and the like, the first gate insulating film 13, a first metal film serving as the first gate electrode 14a and the like, the first interlayer insulating film 15, a second metal film serving as the first relay electrode 18b and the like, a second semiconductor film serving as the second semiconductor layer 16a, the third semiconductor layer 19a, and the like, the common gate insulating film 25, a third metal film serving as the second gate electrode 18a, the third gate electrode 21a, and the like, a fourth metal film serving as the second interlayer insulating film 22, the first terminal electrode 23a, and the like, and the flattening film 24 are sequentially layered on the resin substrate 10.

In the present embodiment, similarly to the TFT layer 30a of the first embodiment described above, the write control TFT 9c, the drive TFT 9d, the power supply control TFT 9e, and the light emission control TFT 9f are provided as the first TFT 9A, the threshold voltage compensation TFT 9b is provided as the second TFT 9B, and the initialization TFT 9a and the anode discharge TFT 9g are provided as the third TFT 9C.

In the organic EL display device 100b in the above-described configuration, as in the operation of the organic EL display device 100a in the first embodiment, in each subpixel P, the organic EL element 35 emits light at a level of a luminance corresponding to a drive current, thereby performing image display.

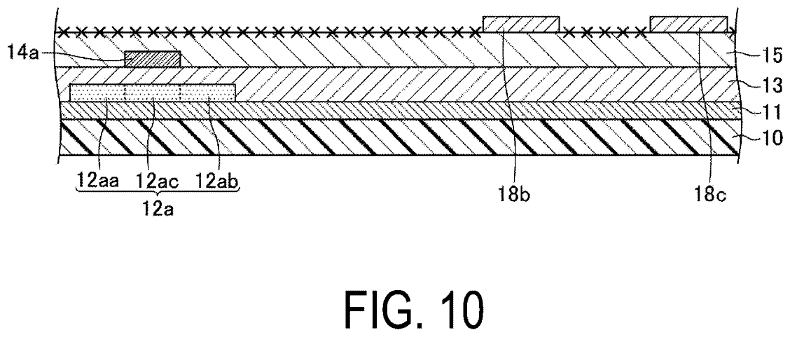

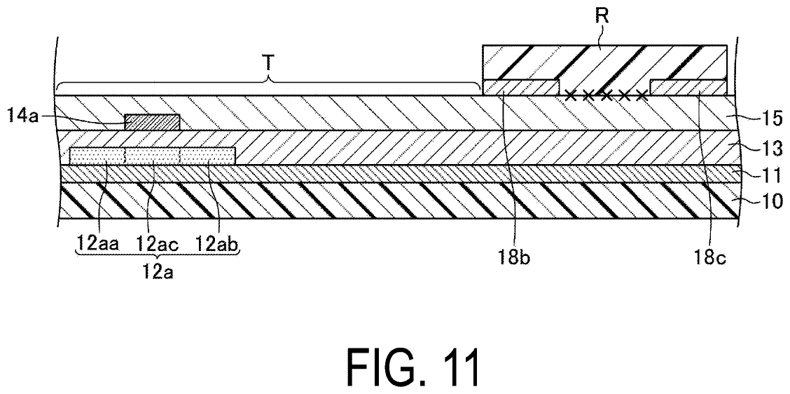

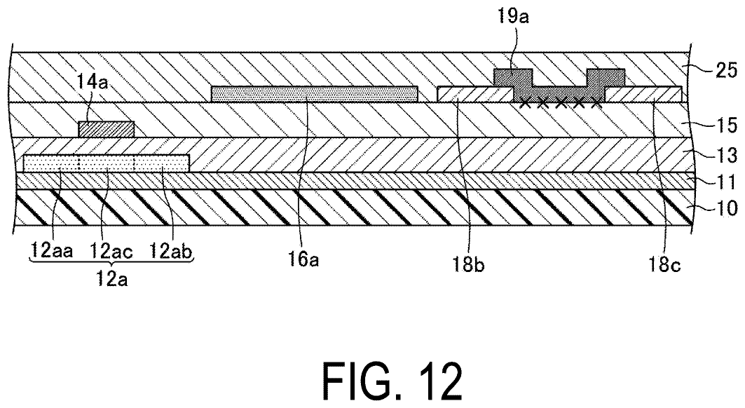

Next, a manufacturing method for the organic EL display device 100b according to the present embodiment will be described. Note that the manufacturing method for the organic EL display device 100b includes TFT layer forming, organic EL element layer forming, and sealing film forming. Here, FIG. 10 is a cross-sectional view illustrating a part of forming the TFT layer 30b. Further, FIG. 11 is a cross-sectional view illustrating a part of forming the TFT layer 30b subsequent to the process illustrated in FIG. 10. Further, FIG. 12 is a cross-sectional view illustrating a part of forming the TFT layer 30b subsequent to the process illustrated in FIG. 11.

### TFT Layer Forming

First, the first interlayer insulating film 15 is formed as in the TFT layer forming of the first embodiment described above.

Next, a molybdenum film (having a thickness of about 250 nm) and the like are formed by, for example, sputtering on the substrate surface on which the first interlayer insulating film 15 is formed to form a second metal film, and then, the second metal film is patterned to form the first relay electrode 18b and the second relay electrode 18c as illustrated in FIG. 10. At this time, on the surface of the first interlayer insulating film 15 exposed from the first relay electrode 18b and the second relay electrode 18c, as indicated by x marks in FIG. 10, oxygen is adsorbed due to oxygen ashing during dry etching using a chlorine-based gas or the like and oxygen adsorbed on residue of the second metal film.

Thereafter, a resist pattern R is formed, on the substrate surface on which the first relay electrode 18b and the like are formed, so as to cover a region between the first relay electrode 18b and the second relay electrode 18c, and then, as illustrated in FIG. 11, a surface treatment T such as dry etching using a fluorine-based gas or the like or wet etching using a hydrofluoric acid or the like is performed on the surface of the first interlayer insulating film 15 exposed from the resist pattern R, thereby partially removing the oxygen absorbed on the surface of the first interlayer insulating film 15.

Furthermore, a second semiconductor film made of an oxide semiconductor is formed by forming a film of InGaZnO₄ or the like (having a thickness of about 30 nm) on the substrate surface from which the resist pattern R has been removed by the surface treatment T, for example, by sputtering, and then, the second semiconductor film is patterned to form the second semiconductor layer 16a, the third semiconductor layer 19a and the like.

Subsequently, a silicon oxide film (having a thickness of approximately 100 nm) is formed by, for example, plasma CVD, on the substrate surface where the second semiconductor layer 16a and the like are formed, thereby forming the common gate insulating film 25 as illustrated in FIG. 12.

Further, on the substrate surface on which the common gate insulating film 25 is formed, a single-layer film of a molybdenum film (having a thickness of about 250 nm), a layered film in which an aluminum film (having a thickness of about 300 nm) and a titanium film (having a thickness of about 50 nm) are sequentially layered, a layered film in which a titanium film (having a thickness of about 50 nm), an aluminum film (having a thickness of about 300 nm), and a titanium film (having a thickness of about 50 nm) are sequentially layered, or the like is formed by sputtering to form a third metal film. Then, the third metal film is patterned to form the second gate electrode 18a, the second scanning signal line 18d, the initialization power supply line 18i, the third gate electrode 21a, and the like.

Furthermore, a silicon oxide film (having a thickness of approximately 300 nm) and a silicon nitride film (having a thickness of approximately 150 nm) are sequentially formed by, for example, plasma CVD on the substrate surface on which the second gate electrode 18a and the like are formed, thereby forming the second interlayer insulating film 22. Note that, by performing heat treatment after forming the second interlayer insulating film 22, a part of the second semiconductor layer 16a and a part of the third semiconductor layer 19a are caused to be conductive, and the third conductor region 16aa, the fourth conductor region 16ab, and the second channel region 16ac are formed in the second semiconductor layer 16a, and the fifth conductor region 19aa, the sixth conductor region 19ab, and the third channel region 19ac are formed in the third semiconductor layer 19a.

Thereafter, at the substrate surface where the second interlayer insulating film 22 is formed, the first gate insulating film 13, the first interlayer insulating film 15, the common gate insulating film 25, and the second interlayer insulating film 22 are patterned as appropriate, thereby forming the first contact hole Ha, the second contact hole Hb, the third contact hole Hc, the fourth contact hole Hd, the fifth contact hole He, and the sixth contact hole Hf.

Furthermore, a fourth metal film is formed by sequentially forming a titanium film (having a thickness of approximately 50 nm), an aluminum film (having a thickness of approximately 400 nm), a titanium film (having a thickness of approximately 50 nm) and the like by sputtering, for example, on the substrate surface at which the first contact hole Ha and the like is formed, and then, the fourth metal film is patterned to form the first terminal electrode 23a, the second terminal electrode 23b, the third terminal electrode 23c, the fourth terminal electrode 23d, the fifth terminal electrode 23e, the sixth terminal electrode 23f, the data signal line 23g, the high-level power supply line 23h, and the like.

Finally, after applying a polyimide-based photosensitive resin film (having a thickness of about 2 μm) to the substrate surface on which the first terminal electrode 23a and the like are formed, by spin coating or slit coating, for example, pre-baking, exposing, developing, and post-baking are performed on the applied film to form the flattening film 24.

As described above, the TFT layer 30b can be formed.

Thereafter, the organic EL element layer forming and the sealing film forming are performed as in the first embodiment, and thus the organic EL display device 100b of the present embodiment can be manufactured.

As described above, according to the organic EL display device 100b of the present embodiment, the threshold voltage compensation TFT 9b provided as the second TFT 9B has the top contact structure, and the initialization TFT 9a and the anode discharge TFT 9g provided as the third TFT 9C have the bottom contact structure. Here, in the initialization TFT 9a and the anode discharge TFT 9g having the bottom contact structure, oxygen is adsorbed on the surface of the first interlayer insulating film 15 when the first relay electrode 18b and the second relay electrode 18c are formed, so that the third semiconductor layer 19a formed thereafter is oxidized. This causes a margin in an off state to be sufficiently ensured in each of the initialization TFT 9a and the anode discharge electrode TFT 9g because the threshold values of the initialization TFT 9a and the anode discharge TFT 9g are likely to go to the positive side. Note that when the light emission control signal EM(n) is at the low level, the light emission control TFT 9f is in an on state and a current flows through the organic EL device 35 to emit light. However, in a case where the anode discharge TFT 9g does not sufficiently enter the off state at this time, the current to flow through the organic EL element 35 flows through the initialization power supply line Vini, and the threshold value of the anode discharge TFT 9g also goes to the positive side, thereby sufficiently ensuring the off margin. On the other hand, in the threshold voltage compensation TFT 9b having the top contact structure, although oxygen is once adsorbed on the surface of the first interlayer insulating film 15 when the first relay electrode 18b and the second relay electrode 18c are formed, oxygen on the surface of the first interlayer insulating film 15 is removed before the second semiconductor layer 16a is formed. Thus, the second semiconductor layer 16a is not oxidized, and the threshold value of the second TFT 9B easily shifts to the negative side, thereby allowing a voltage of a data signal to be sufficiently written to the first gate electrode 14a of the drive TFT 9d. As a result, in the organic EL display device 100b having the hybrid structure including the first TFT 9A using polysilicon and the second TFT 9B and the third TFT 9C using the oxide semiconductor, characteristics of the second TFT 9B and the third TFT 9C using the oxide semiconductor can be appropriately adjusted.

### Third Embodiment

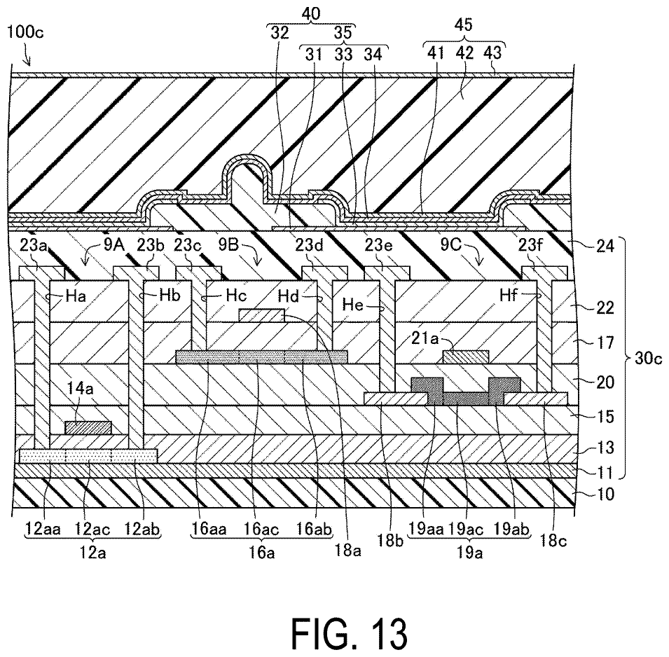

FIG. 13 to FIG. 17 illustrate a third embodiment of a display device according to the disclosure. Here, FIG. 13 is a cross-sectional view of an organic EL display device 100c of the present embodiment.

The first embodiment described above exemplifies the organic EL display device 100a including the TFT layer 30a in which the second semiconductor layer 16a of the second TFT 9B is provided closer to the resin substrate 10 side than the third semiconductor layer 19a of the third TFT 9C is, while the present embodiment exemplifies the organic EL display device 100c including a TFT layer 30c in which the third semiconductor layer 19a of the third TFT 9C is provided closer to the resin substrate 10 side than the second semiconductor layer 16a of the second TFT 9B is.

Similarly to the organic EL display device 100a in the first embodiment, the organic EL display device 100c in the present embodiment includes the display region 50 in which a plurality of subpixels P are provided in a matrix shape, and the gate driver 60, the emission driver 70, and the source driver 80 provided in a frame region around the display region 50. Note that the display control circuit 150 electrically connected to the gate driver 60, the emission driver 70, and the source driver 80 is provided outside the organic EL display device 100c in the present embodiment, similarly to the organic EL display device 100a in the first embodiment.

Additionally, as illustrated in FIG. 13, the organic EL display device 100c includes the resin substrate 10 provided as a base substrate, the TFT layer 30c provided on the resin substrate 10, the organic EL element layer 40 provided on the TFT layer 30c as a light-emitting element layer, and the sealing film 45 provided on the organic EL element layer 40.

As illustrated in FIG. 13, the TFT layer 30c includes the base coat film 11 provided on the resin substrate 10, four first TFTs 9A, one second TFT 9B, two third TFTs 9C, and one capacitor 9h provided on the base coat film 11 for each of the subpixels P, and the flattening film 24 provided on the respective first TFTs 9A, second TFTs 9B, third TFTs 9C, and capacitors 9h.

In the display region 50 of the TFT layer 30c, i pieces of first scanning signal lines PS(1) to PS(i), (i+1) pieces of second scanning signal lines NS(0) to NS(i), i pieces of light emission control lines EM(1) to EM(i), j pieces of data signal lines D(1) to D(j), a high-level power supply line ELVDD, a low-level power supply line ELVSS, and an initialization power supply line Vini are provided, similarly to the TFT layer 30a in the first embodiment.

As illustrated in FIG. 13, the first terminal electrode 23a and the second terminal electrode 23b of the first TFT 9A are respectively electrically connected to the first conductor region 12aa and the second conductor region 12ab of the first semiconductor layer 12a through a first contact hole Ha and a second contact hole Hb formed in a layered film of the first gate insulating film 13, the first interlayer insulating film 15, the third gate insulating film 20, the second gate insulating film 17, and the second interlayer insulating film 22.

As illustrated in FIG. 13, the second TFT 9B includes the second semiconductor layer 16a provided on the third gate insulating film 20, the second gate electrode 18a provided on the second semiconductor layer 16a with the second gate insulating film 17 interposed therebetween, and the third terminal electrode 23c and the fourth terminal electrode 23d provided so as to be separated from each other on the second interlayer insulating film 22. Here, the second TFT 9B has a top contact structure as illustrated in FIG. 13, and a threshold value thereof tends to easily shift to a negative side.

As illustrated in FIG. 13, the third terminal electrode 23c and the fourth terminal electrode 23d are respectively electrically connected to the third conductor region 16aa and the fourth conductor region 16ab of the second semiconductor layer 16a through a third contact hole Hc and a fourth contact hole Hd formed in a layered film of the second gate insulating film 17 and the second interlayer insulating film 22.

As illustrated in FIG. 13, the third TFT 9C includes the third semiconductor layer 19a provided on the first interlayer insulating film 15, the first relay electrode 18b and the second relay electrode 18c provided on the resin substrate 10 side of the third semiconductor layer 19a so as to be separated from each other, the third gate electrode 21a provided on the third semiconductor layer 19a with the third gate insulating film 20 interposed therebetween, and the fifth terminal electrode 23e and the sixth terminal electrode 23f provided on the second interlayer insulating film 22 so as to be separated from each other. Here, as illustrated in FIG. 13, the third TFT 9C has a bottom contact structure, and for example, when a second metal film is patterned by dry etching to form the first relay electrode 18b and the second relay electrode 18c, the oxide semiconductor is oxidized due to oxygen ashing or a small amount of residue of the second metal film, and thus a threshold value tends to shift to a positive side.

As illustrated in FIG. 13, the first relay electrode 18b and the second relay electrode 18c are provided on the first interlayer insulating film 15 and are provided so as to be respectively in contact with the lower surfaces of the fifth conductor region 19aa and the sixth conductor region 19ab of the third semiconductor layer 19a.

As illustrated in FIG. 13, the fifth terminal electrode 23e and the sixth terminal electrode 23f are respectively electrically connected to the first relay electrode 18b and the second relay electrode 18c through a fifth contact hole He and a sixth contact hole Hf formed in a layered film of the third gate insulating film 20, the second gate insulating film 17, and the second interlayer insulating film 22.

Note that in the TFT layer 30c, as illustrated in FIG. 13, the base coat film 11, a first semiconductor film serving as the first semiconductor layer 12a and the like, the first gate insulating film 13, a first metal film serving as the first gate electrode 14a and the like, the first interlayer insulating film 15, the second metal film serving as the first relay electrode 18b and the like, a third semiconductor film serving as the third semiconductor layer 19a and the like, the third gate insulating film 20, a third metal film serving as the third gate electrode 21a and the like, a second semiconductor film serving as the second semiconductor layer 16a and the like, the second gate insulating film 17, a fourth metal film serving as the second gate electrode 18a and the like, the second interlayer insulating film 22, a fifth metal film serving as the first terminal electrode 23a and the like, and the flattening film 24 are layered in this order on the resin substrate 10.

In the present embodiment, similarly to the TFT layer 30a of the first embodiment described above, the write control TFT 9c, the drive TFT 9d, the power supply control TFT 9e, and the light emission control TFT 9f are provided as the first TFT 9A, the threshold voltage compensation TFT 9b is provided as the second TFT 9B, and the initialization TFT 9a and the anode discharge TFT 9g are provided as the third TFT 9C.

In the organic EL display device 100c having the configuration described above, as in the operation of the organic EL display device 100a in the first embodiment described above, in each subpixel P, the organic EL element 35 emits light at a level of a luminance corresponding to a drive current, thereby performing image display.

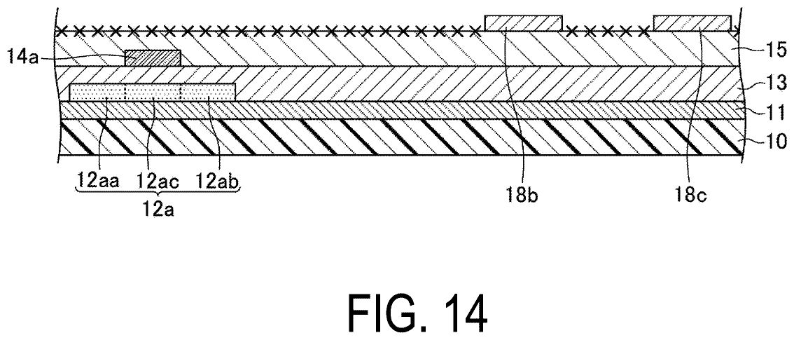

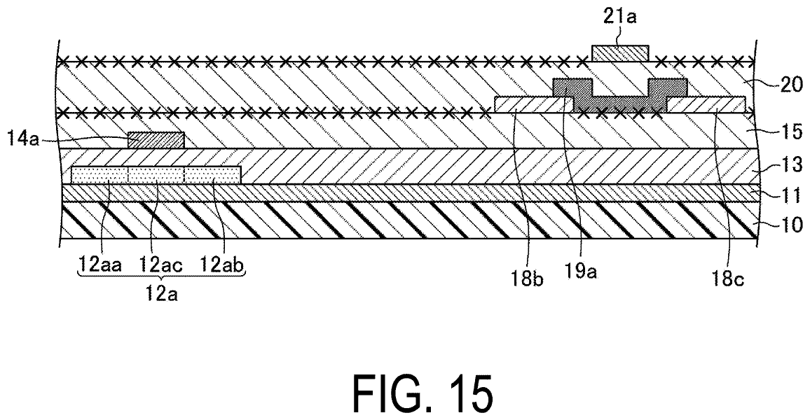

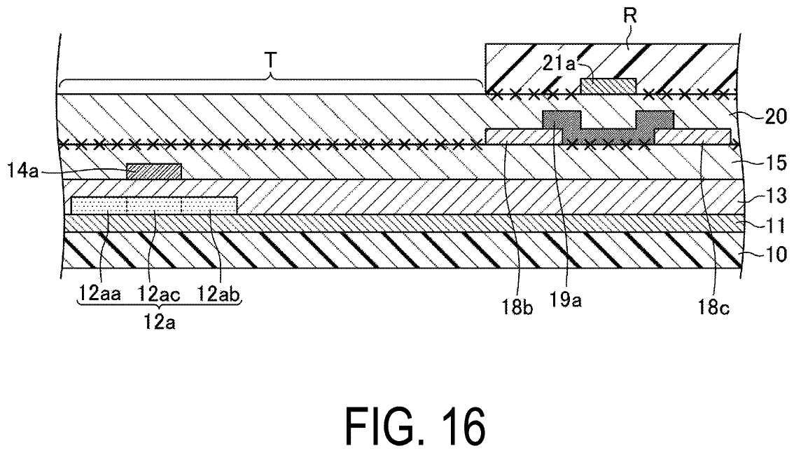

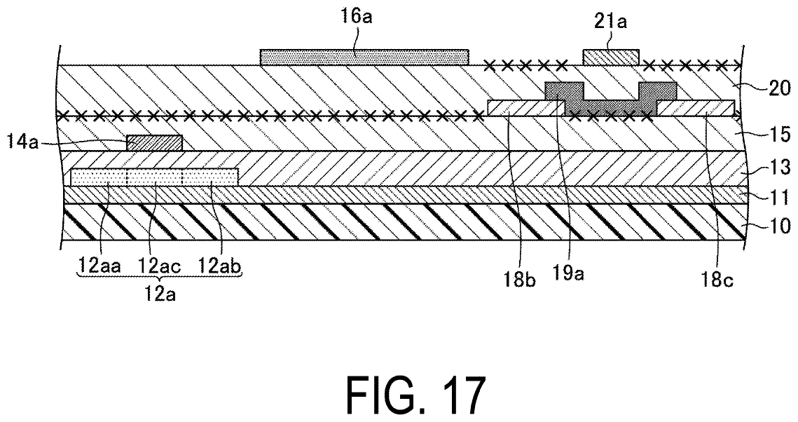

Next, a manufacturing method for the organic EL display device 100c according to the present embodiment will be described. Note that the manufacturing method for the organic EL display device 100c includes TFT layer forming, organic EL element layer forming, and sealing film forming. Here, FIG. 14 is a cross-sectional view illustrating a part of forming the TFT layer 30c. Further, FIG. 15 is a cross-sectional view illustrating a part of forming the TFT layer 30c subsequent to the process illustrated in FIG. 14. Further, FIG. 16 is a cross-sectional view illustrating a part of forming the TFT layer 30c subsequent to the process illustrated FIG. 15. Further, FIG. 17 is a cross-sectional view illustrating a part of forming the TFT layer 30c subsequent to the process illustrated in FIG. 16.

### TFT Layer Forming

First, the first interlayer insulating film 15 is formed as in the TFT layer forming of the first embodiment described above.

Next, a molybdenum film (having a thickness of about 250 nm) or the like is formed by, for example, sputtering on the substrate surface on which the first interlayer insulating film 15 is formed to form a second metal film, and then the second metal film is patterned to form the first relay electrode 18b and the second relay electrode 18c as illustrated in FIG. 14. At this time, on the surface of the first interlayer insulating film 15 exposed from the first relay electrode 18b and the second relay electrode 18c, as indicated by x marks in FIG. 14, oxygen is adsorbed due to oxygen ashing during dry etching using a chlorine-based gas or the like and oxygen adsorbed on residue of the second metal film.

Subsequently, a third semiconductor film made of an oxide semiconductor is formed by forming a film of InGaZnO₄ (having a thickness of about 30 nm) or the like by, for example, sputtering on the substrate surface on which the first relay electrode 18b and the like are formed, and then, the third semiconductor film is patterned to form the third semiconductor layer 19a and the like. At this time, the third semiconductor layer 19a is oxidized by diffusion of oxygen from the surface of the first interlayer insulating film 15 (see FIG. 15).

After that, a silicon oxide film (having a thickness of about 100 nm) is formed, for example, by plasma CVD on the substrate surface on which the third semiconductor layer 19a and the like are formed, to form the third gate insulating film 20.

Furthermore, a third metal film is formed by forming a molybdenum film (having a thickness of approximately 250 nm) or the like by, for example, sputtering on the substrate surface on which the third gate insulating film 20 is formed, and then, the third metal film is patterned to form the third gate electrode 21a and the like, as illustrated in FIG. 15. At this time, oxygen is adsorbed on the surface of the third gate insulating film 20 exposed from the third gate electrode 21a, as indicated by x marks in FIG. 15, due to oxygen ashing during dry etching using a chlorine-based gas or the like and oxygen adsorbed on the residue of the third metal film.

Thereafter, a resist pattern R is formed so as to cover the third gate electrode 21a, and then, as illustrated in FIG. 16, the surface of the third gate insulating film 20 exposed from the resist pattern R is subjected to a surface treatment T such as dry etching using a fluorine-based gas or the like or wet etching using a hydrofluoric acid or the like, thereby partially removing oxygen adsorbed on the surface of the third gate insulating film 20.

Subsequently, a second semiconductor film made of an oxide semiconductor is formed by forming a film of InGaZnO₄ (having a thickness of about 30 nm) or the like by, for example, sputtering on the substrate surface obtained by performing the surface treatment T and removing the resist pattern R, and then, the second semiconductor film is patterned to form the second semiconductor layer 16a and the like, as illustrated in FIG. 17.

Subsequently, a silicon oxide film (having a thickness of approximately 100 nm) is formed by, for example, plasma CVD, on the substrate surface where the second semiconductor layer 16a and the like are formed, thereby forming the second gate insulating film 17.

After that, on the substrate surface on which the second gate insulating film 17 is formed, a single-layer film of a molybdenum film (having a thickness of about 250 nm), a layered film in which an aluminum film (having a thickness of about 300 nm) and a titanium film (having a thickness of about 50 nm) are sequentially layered, a layered film in which a titanium film (having a thickness of about 50 nm), an aluminum film (having a thickness of about 300 nm), and a titanium film (having a thickness of about 50 nm) are sequentially layered or the like is formed by sputtering to form a fourth metal film. Then, the fourth metal film is patterned to form the second gate electrode 18a, the second scanning signal line 18d, the initialization power supply line 18i, the third gate electrode 21a, and the like.

Furthermore, a silicon oxide film (having a thickness of approximately 300 nm) and a silicon nitride film (having a thickness of approximately 150 nm) are sequentially formed by, for example, plasma CVD on the substrate surface on which the second gate electrode 18a and the like are formed, thereby forming the second interlayer insulating film 22. Note that, by performing heat treatment after forming the second interlayer insulating film 22, a part of the second semiconductor layer 16a and a part of the third semiconductor layer 19a are caused to be conductive, and the third conductor region 16aa, the fourth conductor region 16ab, and the second channel region 16ac are formed in the second semiconductor layer 16a, and the fifth conductor region 19aa, the sixth conductor region 19ab, and the third channel region 19ac are formed in the third semiconductor layer 19a.

Thereafter, at the substrate surface where the second interlayer insulating film 22 is formed, the first gate insulating film 13, the first interlayer insulating film 15, the third gate insulating film 20, the second gate insulating film 17, and the second interlayer insulating film 22 are appropriately patterned to form the first contact hole Ha, the second contact hole Hb, the third contact hole Hc, the fourth contact hole Hd, the fifth contact hole He, and the sixth contact hole Hf.

Furthermore, a fifth metal film is formed by sequentially forming a titanium film (having a thickness of approximately 50 nm), an aluminum film (having a thickness of approximately 400 nm), a titanium film (having a thickness of approximately 50 nm) and the like by sputtering, for example, on the substrate surface at which the first contact hole Ha and the like are formed, and then, the fifth metal film is patterned to form the first terminal electrode 23a, the second terminal electrode 23b, the third terminal electrode 23c, the fourth terminal electrode 23d, the fifth terminal electrode 23e, the sixth terminal electrode 23f, the data signal line 23g, the high-level power supply line 23h, and the like.

Finally, after applying a polyimide-based photosensitive resin film (having a thickness of about 2 μm) to the substrate surface on which the first terminal electrode 23a and the like are formed, by spin coating or slit coating, for example, pre-baking, exposing, developing, and post-baking are performed on the applied film to form the flattening film 24.

As described above, the TFT layer 30c can be formed.

Thereafter, the organic EL element layer forming and the sealing film forming are performed as in the first embodiment described above, and thus, the organic EL display device 100c of the present embodiment can be manufactured.

As described above, according to the organic EL display device 100c of the present embodiment, the threshold voltage compensation TFT 9b provided as the second TFT 9B has the top contact structure, and the initialization TFT 9a and the anode discharge TFT 9g provided as the third TFT 9C have the bottom contact structure. Here, in the initialization TFT 9a and the anode discharge TFT 9g having the bottom contact structure, oxygen is adsorbed on the surface of the first interlayer insulating film 15 when the first relay electrode 18b and the second relay electrode 18c are formed, so that the third semiconductor layer 19a formed thereafter is oxidized. This causes a margin in an off state to be sufficiently ensured in each of the initialization TFT 9a and the anode discharge electrode TFT 9g because the threshold values of the initialization TFT 9a and the anode discharge TFT 9g are likely to go to the positive side. Note that when the light emission control signal EM(n) is at the low level, the light emission control TFT 9f is in an on state and a current flows through the organic EL device 35 to emit light. However, in a case where the anode discharge TFT 9g does not sufficiently enter the off state at this time, the current to flow through the organic EL element 35 flows through the initialization power supply line Vini, and the threshold value of the anode discharge TFT 9g also goes to the positive side, thereby sufficiently ensuring the off margin. On the other hand, in the threshold voltage compensation TFT 9b having the top contact structure, although oxygen is once adsorbed on the surface of the third gate insulating film 20 when the third gate electrode 21a is formed, the second semiconductor layer 16a is not oxidized, and the threshold value of the second TFT 9B easily shifts to the negative side because oxygen on the surface of the third gate insulating film 20 is removed before the second semiconductor layer 16a is formed, thereby allowing the voltage of the data signal to be sufficiently written to the first gate electrode 14a of the drive TFT 9d. As a result, in the organic EL display device 100c having the hybrid structure including the first TFT 9A using polysilicon and the second TFT 9B and the third TFT 9C using the oxide semiconductor, characteristics of the second TFT 9B and the third TFT 9C using the oxide semiconductor can be appropriately adjusted.

### OTHER EMBODIMENTS

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

In each of the embodiments described above, the organic EL display device including the first electrode as an anode electrode and the second electrode as a cathode electrode is exemplified. The disclosure is also applicable to an organic EL display device in which the layered structure of the organic EL layer is reversed with the first electrode being a cathode electrode and the second electrode being an anode electrode.

In each of the embodiments described above, the organic EL display device has been exemplified as the display device. The disclosure can also be applied to a display device including a plurality of light-emitting elements to be driven by a current, for example, to a display device including quantum dot light-emitting diodes (QLEDs), each of which is a light-emitting element using a quantum dot-containing layer.

### INDUSTRIAL APPLICABILITY

As described above, the disclosure is useful for a flexible display device.

1. A display device comprising:
a base substrate; and
a thin film transistor layer provided on the base substrate,
wherein the thin film transistor layer is provided with, for each of subpixels constituting a display region, a first thin film transistor including a first semiconductor layer made of polysilicon, a second thin film transistor including a second semiconductor layer made of an oxide semiconductor, and a third thin film transistor including a third semiconductor layer made of an oxide semiconductor,
the first thin film transistor includes the first semiconductor layer in which a first conductor region and a second conductor region are defined to be separated from each other and a first channel region is defined between the first conductor region and the second conductor region, a first gate electrode provided on the first semiconductor layer, the first gate electrode being superimposed over the first channel region with a first inorganic insulating film interposed between the first gate electrode and the first channel region, and a first terminal electrode and a second terminal electrode separated from each other on a side opposite to the base substrate relative to the first gate electrode, the first terminal electrode and the second terminal electrode being respectively electrically connected to the first conductor region and the second conductor region,
the second thin film transistor includes the second semiconductor layer in which a third conductor region and a fourth conductor region are defined to be separated from each other and a second channel region is defined between the third conductor region and the fourth conductor region, a second gate electrode provided on the second semiconductor layer, the second gate electrode being superimposed over the second channel region with a second inorganic insulating film interposed between the second gate electrode and the second channel region, and a third terminal electrode and a fourth terminal electrode separated from each other on a side opposite to the base substrate relative to the second gate electrode, the third terminal electrode and the fourth terminal electrode being respectively electrically connected to the third conductor region and the fourth conductor region, and
the third thin film transistor includes the third semiconductor layer in which a fifth conductor region and a sixth conductor region are defined to be separated from each other and a third channel region is defined between the fifth conductor region and the sixth conductor region, a first relay electrode and a second relay electrode provided on a side of the base substrate of the third semiconductor layer, the first relay electrode and the second relay electrode being disposed respectively in contact with the fifth conductor region and the sixth conductor region, a third gate electrode provided on the third semiconductor layer, the third gate electrode being superimposed over the third channel region with a third inorganic insulating film interposed between the third gate electrode and the third channel region, and a fifth terminal electrode and a sixth terminal electrode separated from each other on a side opposite to the base substrate relative to the third gate electrode, the fifth terminal electrode and the sixth terminal electrode being respectively electrically connected to the first relay region and the second relay region.

2. The display device according to claim 1,
wherein as the first thin film transistor, a write control thin film transistor, a drive thin film transistor, a power supply control thin film transistor, and a light emission control thin film transistor are provided,
as the second thin film transistor, a threshold voltage compensation thin film transistor is provided, and
as the third thin film transistor, an initialization thin film transistor and an anode discharge thin film transistor are provided.

3. The display device according to claim 1,
wherein the first gate electrode is covered by a fourth inorganic insulating film,
the second semiconductor layer is provided on the fourth inorganic insulating film,
the third inorganic insulating film covers the second gate electrode,
the first relay electrode and the second relay electrode are provided on the second inorganic insulating film, and
a fifth inorganic insulating film covers the third gate electrode.

4. The display device according to claim 3,
wherein the first terminal electrode and the second terminal electrode are respectively electrically connected to the first conductor region and the second conductor region through a first contact hole and a second contact hole formed in a layered film of the first inorganic insulating film, the fourth inorganic insulating film, the second inorganic insulating film, the third inorganic insulating film, and the fifth inorganic insulating film,
the third terminal electrode and the fourth terminal electrode are respectively electrically connected to the third conductor region and the fourth conductor region through a third contact hole and a fourth contact hole formed in a layered film of the second inorganic insulating film, the third inorganic insulating film, and the fifth inorganic insulating film, and
the fifth terminal electrode and the sixth terminal electrode are respectively electrically connected to the first relay electrode and the second relay electrode through a fifth contact hole and a sixth contact hole formed in a layered film of the third inorganic insulating film and the fifth inorganic insulating film.

5. The display device according to claim 1,
wherein the first gate electrode is covered by a fourth inorganic insulating film,
the second semiconductor layer, the first relay electrode, and the second relay electrode are provided on the fourth inorganic insulating film,
the second inorganic insulating film and the third inorganic insulating film are provided as a common inorganic insulating film, and
the second gate electrode and the third gate electrode are covered by a fifth inorganic insulating film.

6. The display device according to claim 5,
wherein the first terminal electrode and the second terminal electrode are respectively electrically connected to the first conductor region and the second conductor region through a first contact hole and a second contact hole formed in a layered film of the first inorganic insulating film, the fourth inorganic insulating film, the common inorganic insulating film, and the fifth inorganic insulating film,
the third terminal electrode and the fourth terminal electrode are respectively electrically connected to the third conductor region and the fourth conductor region through a third contact hole and a fourth contact hole formed in a layered film of the common inorganic insulating film and the fifth inorganic insulating film, and
the fifth terminal electrode and the sixth terminal electrode are respectively electrically connected to the first relay electrode and the second relay electrode through a fifth contact hole and a sixth contact hole formed in a layered film of the common inorganic insulating film and the fifth inorganic insulating film.

7. The display device according to claim 1,
wherein the first gate electrode is covered by a fourth inorganic insulating film,
the first relay electrode and the second relay electrode are provided on the fourth inorganic insulating film,
the second semiconductor layer is provided on the third inorganic insulating film,
the second inorganic insulating film covers the third gate electrode, and
the second gate electrode is covered by a fifth inorganic insulating film.

8. The display device according to claim 7,
wherein the first terminal electrode and the second terminal electrode are respectively electrically connected to the first conductor region and the second conductor region through a first contact hole and a second contact hole formed in a layered film of the first inorganic insulating film, the fourth inorganic insulating film, the third inorganic insulating film, the second inorganic insulating film, and the fifth inorganic insulating film,
the third terminal electrode and the fourth terminal electrode are respectively electrically connected to the third conductor region and the fourth conductor region through a third contact hole and a fourth contact hole formed in a layered film of the second inorganic insulating film and the fifth inorganic insulating film, and
the fifth terminal electrode and the sixth terminal electrode are respectively electrically connected to the first relay electrode and the second relay electrode through a fifth contact hole and a sixth contact hole formed in a layered film of the third inorganic insulating film, the second inorganic insulating film, and the fifth inorganic insulating film.

9. The display device according to claim 1, further comprising:
a light-emitting element layer provided on the thin film transistor layer, the light-emitting element layer including a plurality of light-emitting elements arrayed in correspondence with a plurality of subpixels included in the display region; and
a sealing film provided on the light-emitting element layer.

10. The display device according to claim 9,
wherein each of the plurality of light-emitting elements is an organic electroluminescence element.
